(19) United States
(12) Patent Application Publication
(10) Pub. No.: US 2026/0026301 A1
(43) Pub. Date: Jan. 22, 2026

(54) METHOD AND DEVICE FOR PRODUCING CONTACT METALLIZATIONS

(71) Applicant: Pac Tech – Packaging Technologies GmbH, Nauen (DE)

(72) Inventors: Thorsten Krause, Hoppegarten (DE); Thierry Bro, Berlin (DE)

(21) Appl. No.: 19/271,697

(22) Filed: Jul. 16, 2025

(30) Foreign Application Priority Data
Jul. 18, 2024 (DE) 10 2024 120 350.1

(51) Int. Cl. H01L 21/677; H01L 21/67

(52) U.S. Cl. CPC H01L 21/67715; H01L 21/67207; H01L 21/67253; H01L 21/67276; H01L 21/67706

(57) ABSTRACT

A method and device for producing contact metallizations on terminal faces of wafers by a manipulator unit for handling the wafers and a plurality of work stations each having a processing space for receiving the wafers, the plurality of work stations including a depositing station, which has a processing space for receiving a solution of contact metal dissolved in a carrier liquid for deposition on the terminal faces of the wafers, detecting a measured value of an object property of a wafer or of a work station by a sensor, and determining a prioritization of equipping the processing spaces or a dwell time of the wafers in a processing space by querying the measured value in a databank or by means of inference using a statistic model while entering the measured value, generating a control dataset for the manipulator unit; and handling the wafers according to the control dataset.

This application claims priority to German Patent Application No. 10 2024 120 350.1 filed on Jul. 18, 2024, the disclosure of which is hereby incorporated by reference.

### TECHNICAL FIELD

The present invention relates to a method and a device for producing contact metallizations on terminal faces of wafers by means of a manipulator unit for handling the wafers and by means of a plurality of work stations, preferably disposed in a line, each having a processing space for receiving the wafers, the plurality of work stations comprising as a work station at least one depositing station which has a processing space for receiving a solution of contact metal dissolved in a carrier liquid for deposition on the terminal faces of the wafers.

### BACKGROUND

The production of contact metallizations, which are also referred to as under-bump metallizations (UPM) in technical terms, on the terminal faces of chips takes place at wafer level as standard, i.e. the entire wafer with the multitude of chips formed on it undergoes a chemical process before the chips are separated from the wafer, in which an intermediate metallization known as under-bump metallization is applied to the terminal faces of the chips, which in the initial state have a surface metallization of aluminum or copper, the intermediate metallization serving as an adhesive base for subsequently applied solder bumps made of a solder material. The chips are separated from the wafer only subsequently to the application of the solder bumps.

A device for producing such contact metallizations, which is known, for example, from CN 203760439 U, regularly comprises a depositing station with a basin forming a processing space for receiving, for example, a nickel solution, which usually contains nickel dissolved in nitric acid. When a wafer is received in the processing space, nickel can then be deposited from the nickel solution on a terminal face of the wafer as a contact metal. This process for forming the contact metallization on the terminal faces of the chips must be carried out under cleanroom conditions in order to preclude the formation of defects as far as possible. To carry out the process, which in particular includes cleaning and rinsing treatment of the wafers prior to the deposition of contact metals for the formation of contact metallization, a large number of devices and specifications are required which on the one hand enable the process to be controlled, in particular with regard to the allocation of the wafers to the different work stations and the dwell time of the wafers in the work stations, and on the other hand provide the media required for carrying out the process, such as deionized water for rinsing processes or metal-containing solutions for the deposition of the contact metallization.

The requirements for carrying out the process outlined above mean that the user must provide the appropriate process parameters and equipment in order to be able to produce the contact metallization with the necessary reliability. In addition to a considerable structural expenditure, this also requires a great deal of effort for providing and defining the process parameters, which is based on experience according to the generic state of the art. This effort ultimately also has an effect on the manufacturing costs of bondable chips, i.e. chips provided with solder bumps for subsequent contacting.

### SUMMARY

The object of the invention at hand is therefore to propose a method and a device which both automate and simplify the production of contact metallizations on terminal faces of chips, ensure a high and constant quality and moreover allow an inexpensive production of corresponding chips.

This object is attained in a surprisingly simple yet effective manner by a method for producing contact metallizations on terminal faces of wafers having the features of claim 1 and a device for producing contact metallizations on terminal faces of wafers having the features of claim 10.

According to the invention, a method for producing contact metallizations on terminal faces of wafers by means of a manipulator unit for handling the wafers and by means of a plurality of work stations, preferably disposed in a line, each having a processing space for receiving the wafers is proposed, the plurality of work stations comprising as a work station at least one depositing station which has a processing space for receiving a solution of contact metal dissolved in a carrier liquid for deposition on the terminal faces of the wafers, comprising the following steps:
a. detecting at least one measured value of at least one object property of a wafer and/or of a work station by means of at least one sensor of a sensor unit;
b. determining a prioritization of equipping the process spaces and/or a dwell time of the wafers in a processing space by means of querying the measured value in a databank or by means of inference using a statistical model while entering the measured value;
c. generating a control dataset for the manipulator unit, taking into account the prioritization and/or dwell time determined in step b.; and
d. handling the wafers by means of the manipulator unit according to the control dataset.

In the context of the invention, it has been recognized that the handling of wafers, in particular a plurality of wafers that can be received in a transport receptacle, is extremely complex and dependent on a variety of influences. In the context of the invention, the plurality of wafers may also be referred to as a wafer package. A reliable, safe and time-optimized contact metallization of wafers often fails because no prioritization of equipping the process spaces and/or a dwell time of the wafers in a processing space can be determined and consequently only a single transport receptacle is conveyed through the device for producing contact metallizations, the wafers received in the transport receptacle passing through the process spaces of the work station according to a strictly predetermined sequence and dwell time. In the context of the invention, however, it has been recognized that it is advantageous to determine a prioritization of equipping the process spaces and/or a dwell time of the wafers in one of the process spaces, taking into account ambient influences, the current position of the wafers and/or the composition of the contents of the process spaces of the individual work stations. The method according to the invention makes it possible to reliably produce contact metallizations on the terminal faces of the wafers, taking into account at least the aforementioned parameters, and thus to react to changes in the surroundings of the production of the wafers and/or the contents of the process spaces at short notice and as automatically as possible.

For this purpose, in step a. at least one measured value of at least one object property of a wafer and/or of a work station is detected by means of at least one sensor of a sensor unit. This means that a property of a wafer, for example the weight of the wafer, the temperature of the wafer, the purity and/or the thickness of a contact metallization applied to the wafer on the terminal faces is detected. Additionally or alternatively, an object property of a work station, for example the composition of the in particular liquid content of the processing space of the work station, the temperature within the processing space of the work station or of the liquid contained in the processing space of the work station, or the period of time over which a liquid is provided in the processing space, can be detected. The measured values can be detected by means of a sensor of a sensor unit. It is conceivable that the sensor detects several identical object properties simultaneously or successively. For example, the sensor detects the weight of one or more wafers simultaneously or consecutively. It is also conceivable that the sensor unit has a data processing unit and that the measured value is obtained by calculation from the data detected by the sensor in the data processing unit. Preferably, a plurality of identical or different measured values are measured.

The term “object property” relates to a state variable and/or a characteristic assigned to the object, which allows conclusions to be drawn about the identity, the type and/or the composition of the wafer and/or the content of a processing space of a work station.

The term “measured value” relates to the quantization, the expression and/or the digitization of an object property.

In step b., the measured value measured in step a. is queried in a databank and/or is entered into a statistical model. At least one prioritization of equipping the process spaces and/or a dwell time of the wafers in a processing space can be unambiguously stored in the databank for any number of measured values. In the context of the invention, the term “dwell time” relates to the period of time that a wafer or a wafer package spends in a processing space of a work station. In the context of the invention the term “prioritization” relates to the establishment of a sequence according to urgency. In the present case, the prioritization relates to the establishment of a sequence of equipping the process spaces depending on the urgency. For example, a transport receptacle with wafers of high priority is handled by the manipulator unit before a transport receptacle of low priority. Furthermore, optimal path planning of the manipulator unit can be taken into account during prioritization. The path planning concerns the geometric path planning of the manipulator unit in its working space. The path planning can be optimized in terms of distance, path duration and acceleration forces when the manipulator unit starts up and slows down.

If the query of the measured value in the databank is successful, i.e. the queried measured value is stored in the databank, the databank returns the prioritization of equipping the process spaces and/or a dwell time of the wafers in a processing space. Additionally or alternatively, the measured value can be entered into a statistical model. The statistical model can be trained after, before and/or during the execution of the method by means of training data sets comprising at least training measured values. The statistical model infers at least one, preferably an optimal, prioritization of equipping the process spaces and/or dwell time of the wafers in a processing space from the measured value. It is conceivable that the statistical model infers the at least one, preferably optimal, prioritization of equipping the process spaces and/or dwell time of the wafers in a processing space from the fact that all detected and weighted measured values have the best match with the training measured values of a corresponding object property of a wafer and/or a work station and therefore the prioritization and/or dwell time stored for this wafer and/or this work station is the, preferably optimal, prioritization and/or dwell time. Even more preferably, it is conceivable that the statistical model infers the, preferably optimal, prioritization and/or dwell time from the fact that the individual detected and weighted measured values have the best match with individual training measured values and the prioritization and/or dwell time stored for the individual training measured values is the optimal prioritization and/or dwell time. In other words, the inference of the statistical model corresponds to the prioritization and/or dwell time of a certain other wafer and/or work station, or the inference is formed from different prioritizations and/or dwell times of different wafers and/or work stations. Thus, advantageously, with reference to historical data stored in the databank, the prioritization of equipping the process spaces and/or a dwell time of the wafers in a processing space can be carried out by means of inference, even if no measured value of the databank can be directly assigned to the measured value detected in step a. via a query in the databank. The databank can be created specifically for the method according to the invention. However, it is also conceivable that the databank is generally accessible and/or is intended for other processes. In this case, the databank is used for general networking for digital accessibility of measured values, prioritization and dwell times, and the method uses the stored information. Thus, by linking several devices for contact metallization, the method has access to a multitude of measured values and prioritizations linked to the measured values and/or dwell times linked to the measured values.

The term “optimal prioritization and/or dwell time” refers to a prioritization and/or dwell time that an informed and knowledgeable person skilled in the art, knowing the work stations and the wafers, would classify as optimal in terms of quality requirements and process efficiency in the given surroundings in which the process is carried out.

The term “inference” refers to the derivation of at least one new prioritization and/or at least one new dwell time by means of the statistical model, preferably created by training. The statistical model is preferably designed as a machine-learning model. The statistical model is preferably created in such a way that statistical correlations, structures and/or patterns between the measured values and the output value, namely in the present case a prioritization and/or a dwell time, are recognized. In other words, the statistical model can be trained with the aid of historical data comprising at least measured values and output values and/or with the aid of further datasets provided, the data used to train the model also being referred to as training data sets. Preferably, the training is supervised learning, unsupervised learning or reinforcement learning. Particularly preferably, the statistical model comprises an artificial neural network, in particular a recurrent neural network (RNN), a feedforward neural network (FNN), a convolutional neural network (CNN), a transformer, a flow-based generative model, an evolving neural network, an encoder-decoder model, a variational autoencoder, an autoregressive model (ARMA model), a restricted Boltzmann machine (RBM) and/or a diffusion model, a hidden Markov model (HMM) and/or a support vector machine (SVM). It is also conceivable to use the methods of genetic programming, boosting, decision-tree machine learning, kernel density estimation (KDE), expert systems(ES), a (naive) Bayes classifier, gradient boosting, linear discriminant analysis the nearest neighbor classifier, a cluster analysis method, in particular the single linkage method, the complete linkage method and the Ward method, the K-Means algorithm, the fuzzy C-means algorithm, the expectation-maximization algorithm (EM algorithm), the DBSAN (density-based spatial clustering of applications with noise), the

STING algorithm (statistical information grid-based clustering algorithm) and/or the CLIQUE algorithm (clustering inquest algorithm), and/or a method of anomaly detection, in particular the local outlier factor (LOF), the isolation forest and/or the autoencoder, and/or the principal component analysis (PCA). Furthermore, reinforcement learning methods can be used, such as associative reinforcement learning, deep reinforcement learning, adversarial deep reinforcement learning, fuzzy reinforcement learning and/or safe reinforcement learning. In particular, it is conceivable that methods for clustering data are also used. The skilled person is aware of suitable measures for generating, using and/or training a statistical model. It is also conceivable that the training data sets are stored in a databank, the databank being continuously upgraded by new training data sets during operation or use of the method according to the invention.

Furthermore, it is obvious to a person skilled in the art that the measured value is dependent on the type of sensor used and, depending on the type of sensor used, the measured value also influences the transmission of the prioritization and/or the dwell time of the wafers in a processing space. For example, in one embodiment, the sensor unit can have a time sensor and a position sensor, and the measured values can thus be a time value and a position of the wafer, whereby a dwell time of the wafers in a processing space of a work station can be determined and an optimum dwell time of the wafers in a processing space can be determined by querying the measured value in a databank and/or by inference using a statistical model while entering the measured values in step b. On the other hand, if the position of several different transport receptacles equipped with wafers is detected in step a. and the time already spent by the transport receptacles in a work station is determined by means of a time sensor, a prioritization of equipping the processing spaces still to be passed through by this transport receptacle can take place, so that optimum path planning of the manipulator unit is possible. Preferably, in step b. the prioritization of equipping the process spaces and a dwell time of the wafers in a processing space are determined.

In step c., a control dataset for the manipulator unit is generated taking into account the prioritization and/or dwell time determined in step b. It is also conceivable that further information that is not stored in the databank, for example, is taken into account when generating the control dataset. This information can preferably relate to the manipulator unit and/or to the work station, in particular to a status of the manipulator unit and/or of the work station, so that, for example, a work station that is in a maintenance state is temporarily not controlled and equipped with wafers. The additional information can also relate to the surroundings in which the process is carried out, for example the ambient temperature. It is also conceivable that further information is provided directly by a user, so that the user implementing the method can influence the control dataset. The control dataset provides the manipulator unit with paths and/or movement sequences, in particular which wafers are to be fed into which work station at which time.

In step d., the manipulator unit handles the wafers according to the control dataset. This means that the manipulator unit executes the movement sequences specified by the control dataset. For example, the manipulator unit feeds a first transport receptacle with wafers to a first work station and a second transport receptacle with wafers to a further work station on the basis of the control dataset, taking into account the prioritization determined in step b.

By means of the method according to the invention, it is possible to automatically feed several wafers, in particular several different wafer packages, which are received on a transport receptacle, to different work stations by means of a manipulator unit in a simple, fast and easily adaptable manner depending on a prioritization and/or dwell time. The wafers can be transported between the work stations in the correct prioritized sequence. It can be ensured that the most important wafers and/or the most important transport receptacle, i.e. the transport receptacle with the highest prioritization, is/are always transported and/or treated preferentially. The prioritization can be changed flexibly, taking external and internal influences into account. Thus, with the method according to the invention, a plurality of transport receptacles can also be inserted into the device comprising several work stations and the individual transport receptacle can be handled according to priority without influencing the metallization result of the wafers located on other transport receptacles. Also, by taking into account the dwell time and the prioritization of equipping the process spaces of the work stations, different coatings, in particular with regard to composition and coating thickness, can be automatically applied to the terminal faces of the wafers. A further advantage of the method according to the invention is that the quality of the contact metallization can be further enhanced by the creation of inferences, since the optimum times for the removal from and/or equipment of a processing space and for the transport of the wafers can be constantly redetermined by machine learning, taking into account a wide variety of influences. This can also minimize operator errors and the dependence on an operator's experience can be reduced to a minimum. By taking into account the travel times and acceleration forces, the wafers can also be handled smoothly, reliably, safely and quickly.

Advantageous embodiments of the invention are the subject matter of the dependent claims. All combinations of at least two features disclosed in the description, the claims and/or the figures also fall within the scope of the invention. It is understood that the explanations given with respect to the method in an equivalent manner relate to the device according to the invention, without being mentioned separately for the latter. In particular, it is understood that customary linguistic transformations or a meaningful replacement of respective terms in the context of customary linguistic practice, in particular the use of synonyms supported by the generally recognized linguistic literature, are included in the present disclosure without being explicitly mentioned in their respective formulation.

The object property in step a. can be a property inherent to the wafer or to the working space, a property influenced by the surroundings and/or a property assigned to the wafer or to the working space. A property inherent to the wafer is in particular, but by no means exclusively, the volume, the contour, the dimension, the weight and/or the temperature of the wafer. If a plurality of wafers, which are arranged as a wafer package on a transport receptacle, are moved together between the work stations and are fed to the work stations, the properties inherent in the wafer also relate in an equivalent manner to the plurality of wafers received in a transport receptacle and thus to the wafer package. A property inherent to the work station, in particular to the processing space of the work station, can be the volume, the contour, the dimension, the fill level, the content, the aggregate state of the content, the density of the content, the composition of the content, the refractive index of the content, the dwell time of the content in the processing space and/or the temperature of the content. A property influenced by the surroundings can be the position, the orientation within the device, the orientation in relation to other work stations, the accessibility of a work station, in particular a processing space of a work station, or the ambient temperature. A property assigned to the wafer and/or to the work station can be, for example, an identification number, an identification name, a product number, a product name, an article number and/or an article name. In principle, it is arbitrary what the object property is, as long as the measured value representing it permits an inference to at least one prioritization and/or dwell time and/or a retrieval of at least one control dataset, taking into account the prioritization and/or dwell time determined in step b. in a databank. The object properties listed above enable the detection of a measured value representing them, which is particularly suitable for being compared with a databank and/or for allowing inferences to be made about an optimal prioritization and/or dwell time. In particular, the properties assigned to the wafer and/or the work station are particularly suitable for comparison with a databank. The object properties inherent to the wafer and/or to the work station are particularly suitable for matching the associated measured value with a statistical model.

According to an advantageous embodiment of the method, the prioritization and/or the dwell time in step b. can be determined taking into account the handling paths between the processing spaces of the work stations to be equipped, the handling times for transporting the wafers between the processing spaces to be equipped, the inertia force during handling, the processing time in the processing spaces to be equipped and/or the tolerance bands of the processing times in the processing spaces to be equipped. When determining the prioritization and/or the dwell time in step b., the required processing times, i.e. the times that the wafer optimally spends in a processing space of a work station, and the associated tolerance bands, i.e. the possible deviations from the processing time in order to obtain a result that just meets the requirements, can thus be taken into account. Furthermore, the saturation of the solution received in a processing space can also be taken into account, as the dwell time must be adjusted for an optimal result depending on the saturation of the solution received in a processing space. In addition, handling paths and handling times required to transport the wafers between the work stations and the acceleration forces occurring during the process can be taken into account. It has been recognized in the context of the invention that low acceleration forces are advantageous when transporting the wafers.

In the context of the invention, the term “handling path” refers to the path along which the wafers are moved by the manipulator unit, wherein in particular a gripper or end effector of the manipulator unit covers a travel path. In the simplest case, the travel path of the manipulator unit, in particular of a gripper or end effector of the manipulator unit, can correspond to the handling path for transporting the wafers. Furthermore, in the context of the invention, the term “handling time” relates to the period of time over which the wafers are moved by the manipulator unit, wherein in particular a gripper or end effector of the manipulator unit covers a travel path within a travel time. In the simplest case, the travel time of the manipulator unit, in particular of a gripper or end effector of the manipulator unit, can correspond to the handling time for transporting the wafers.

The prioritization determined in step b. can include a sequence for equipping the processing spaces and/or a path planning of the manipulator unit. The prioritization determined specifies to the manipulator unit which wafers and/or which wafer package should be handled with priority. The path planning of the manipulator unit specifies the exact geometric paths within its working space. Preferably, the path planning of the manipulator unit takes into account the sequence in which the processing spaces are equipped.

According to an advantageous embodiment, in step b. the databank and/or the statistical model can be expanded and/or updated. The expansion of the databank and/or of the statistical model can be upgraded and/or updated with the measured value measured in step a. and/or with the prioritization determined in step b. and/or with the dwell time determined in step b. In the context of the invention, it has been recognized that the object properties of the wafer and/or of a work station, in particular the content of a processing space of a work station, can change temporarily or permanently. The cause for this is basically arbitrary, possible conceivable causes being, for example, a change in the temperature of the wafer and/or a standing time of a solution in a processing space. It has also been recognized that the statistical model can be used to infer optimal prioritizations and/or dwell times in particular if the statistical model is trained with a multitude of typical data, also known as training data sets. The measured values of object properties, which occur when the process is carried out, represent such typical data, which are particularly suitable for training the statistical model. By upgrading and/or updating the databank and/or the statistical model, the process is constantly improved and kept up to date during operation.

It has further been recognized as advantageous that the handling comprises gripping, picking up, lifting, transporting, releasing and/or equipping a processing space of a work station with a wafer and/or a plurality of wafers received in a transport receptacle. Basically, it is arbitrary how the handling of the wafers by means of the manipulator unit is carried out, as long as the handling is carried out according to the prioritization and/or the dwell time of the wafers. In the context of the invention, the term “equipping” relates to the insertion of a wafer and/or of a plurality of wafers into a processing space of a work station, in particular into a solution received in the processing space.

According to an embodiment of the method, step d. may further comprise evaluating the handling and obtaining an evaluation. By means of this evaluation, it is possible to assess the quality of the handling. Advantageously, it is further enabled to expand and/or update the prioritization and/or dwell time in the databank and/or in the statistical model by means of the evaluation in order to obtain the advantages of expanding and/or updating the databank and/or the statistical model described elsewhere. In this way, the handling of the wafers by means of the manipulator unit can be continuously optimized during operation. In particular, the statistical model can be continuously trained, improved and/or adapted by the evaluation, so that even with measured values and/or object properties that cannot be queried in the databank, the statistical model can be used to infer the optimal prioritization and/or dwell time with a higher probability when the method according to the invention is repeated. It is conceivable to carry out the evaluation using the existing sensors or using sensors specially installed for the evaluation. The control dataset can be updated and/or upgraded in step d., taking the evaluation into account. In this way, it is possible to detect possible faulty handling and/or handling that endangers the wafer during handling and to prevent deterioration and/or damage to the wafer during handling by adapting the control dataset, preferably in real time.

According to an advantageous embodiment, at least three, preferably four, transport receptacles holding a plurality of wafers can be handled by means of the manipulator unit in the plurality of work stations. Due to the prioritization of equipping the processing spaces and/or the dwell time of the wafers in a processing space determined in step b., at least three, preferably four, transport receptacles can be reliably handled within the device comprising the work station and can be optimally provided with contact metallizations on the terminal faces of the wafers.

In a further aspect, the invention relates to a device for producing contact metallizations on terminal faces of wafers. The device is suitable for carrying out the method according to the invention. The device according to the invention comprises a plurality of work stations, each having a processing space for receiving the wafers. The plurality of work stations are preferably disposed in a line. The plurality of work stations comprise at least one depositing station, the depositing station comprising a processing space for receiving a solution of contact metal dissolved in a carrier liquid for deposition on the terminal faces of a wafer. The device also comprises a manipulator unit for handling the wafers. The manipulator unit can be designed as a robot. The contact metal dissolved in the carrier liquid can preferably be nickel, zinc, palladium or gold. The device is characterized in that the manipulator unit equipping the processing spaces with wafers according to a selectable prioritization or a selectable dwell time in the processing spaces of the work station. For this purpose, the device comprises a sensor unit and a control unit, the control unit being configured to control a movement of the manipulator unit for equipping the processing spaces as a function of at least one measured value detected by the sensor unit. In other words, the control unit is configured to control the handling of the wafers by means of the manipulator unit and, in particular, to determine a sequence of the processing spaces to be equipped.

A work station, in particular the depositing station, can comprise a basin arrangement with a basin forming the processing space for receiving a liquid, in particular a solution of contact metal dissolved in a liquid. In the depositing station, the contact metal can be deposited on the wafer received in the processing space, in particular on a terminal face of the wafer. The individual work stations can be designed as modules. Thus, with the device according to the invention, a plurality of wafers can be fed to different work stations and/or different work stations can be equipped with wafers, a contact metallization as required being applicable to the terminal faces of the wafers in accordance with a selectable prioritization and/or a selectable dwell time in the processing spaces.

Equipping the processing spaces can be controlled by the device as a function of at least one measured value detected by the sensor unit, so that the selectable prioritization and/or the selectable dwell time in the processing spaces can be adapted on the basis of the measured values detected by the sensor unit. Preferably, both the prioritization and the dwell time in the processing spaces are taken into account when the processing spaces are equipped.

The sensor unit can have a position sensor, an acceleration sensor, a weight sensor, a temperature sensor and/or a chemical sensor for analyzing the liquid in one of the processing spaces and/or for monitoring the deposition on the terminal faces of the wafers. The position sensor can preferably be used to determine the current position of the manipulator unit and/or of a wafer and/or a wafer package within the device. The temperature sensor can preferably be used to detect the temperature of a liquid in a processing space, to detect the ambient temperature inside the device, to detect the ambient temperature outside the device and/or to detect the temperature of a wafer and/or a wafer package. With the chemical sensor for analyzing the liquid, in particular for analyzing the solution of a contact metal dissolved in a carrier liquid, conclusions can be drawn about the liquid in one of the processing spaces, in particular the service life of the liquid and the need to replace the liquid can be determined. It is conceivable that the dwell time in one of the processing spaces is adjusted depending on the service life of the liquid in the respective processing space. A chemical sensor can also be used to monitor the deposition of the contact metal on the terminal faces of the wafers. For example, it is possible to monitor the extent to which a sufficient layer thickness of contact metal is deposited on the terminal faces of the wafer.

The device can comprise a transport receptacle with a plurality of wafers received therein, the processing space being configured to receive the transport receptacle with a plurality of wafers received therein and the manipulator unit being configured to handle the transport receptacle. The transport receptacle can preferably be inserted from above into a processing space, in particular into a basin of a work station. This makes it possible to feed a plurality of wafers to a processing space at the same time. The transport receptacle can be designed in the form of a basket. In the transport receptacle, the wafers can be arranged parallel to each other, evenly spaced and positioned in a vertical or horizontal orientation. Abutment elements can be arranged on the bottom wall of the processing space, in particular a basin, on which the transport receptacle with the wafers received therein can be supported. The manipulator unit for handling the transport receptacle can in particular be configured to move the transport receptacle in a vertical direction in order to insert the transport receptacle into a processing space, in particular into a basin of a work station, and then remove it again from the processing space. Nevertheless, it may also be possible to use the manipulator unit to move the transport receptacles vertically in order to enable the transport receptacle to be moved to different work stations.

Advantageously, the manipulator unit can comprise a conveyor unit. The conveyor unit can have a horizontally displaceable carrier connected to a conveyor belt of the conveyor unit having at least one gripping arm that is displaceable vertically in relation to the carrier. The conveyor belt can be driven by a drive motor. The carrier can have a conveyor belt by means of which the gripping arm can be displaced in relation to the carrier, the conveyor belt being able to be driven by a drive motor of the carrier. The gripping arm can be designed as a receptacle. The sensor unit can comprise sensors for monitoring a current of one of the drive motors and/or the drive motors, a temperature of one of the drive motors and/or the drive motors, a position of the carrier and/or of the gripping arm, an acceleration of the carrier and/or of the gripping arm and/or a tension of one of the conveyor belts and/or the conveyor belts. The transport receptacle can have receiving elements which can be used to grip the transport receptacle by means of the gripping arm. If the transport receptacle has an identification element, such as a barcode or an RFID transponder, the device can comprise a reading device and/or an identification device for reading out and/or identifying the identification element. This makes it possible to assign the transport receptacle to the process sequence and/or to monitor the transport receptacle in the process sequence.

Alternatively or additionally, the manipulator unit can be designed as a multi-axis robot for handling the wafers. The end effector of the robot can be designed as a gripping arm. The gripping arm can in turn be designed as a receptacle. The transport receptacle can have receiving elements that can be used to grip the transport receptacle by means of the gripping arm of the robot. The sensor unit can comprise sensors for monitoring a current of one of the drive motors and/or the drive motors of the robot, a temperature of one of the drive motors and/or the drive motors of the robot, a position of the end effector of the robot and/or an acceleration of the end effector of the robot.

The device can preferably have an input/output station for equipping the device with at least one transport receptacle and/or for removing the transport receptacle from the device. Furthermore, the plurality of work stations can comprise as a work station at least one cleaning station, at least one rinsing station and/or at least one drying station. In a processing space of the cleaning station, the wafers, in particular a transport receptacle with the wafers received therein, can be received and subjected to cleaning, preferably chemical and/or physical cleaning. In a processing space of the rinsing station for receiving the transport receptacle with the wafers held therein any residues can be removed from the wafer surfaces. Rinsing in the rinsing station is preferably carried out with deionized water. The input/output station can have drawers, which are preferably automatically retractable and extendable. The drawers can be part of the manipulator unit and can each be retracted and extended by means of a drive motor. Alternatively or additionally, a respective handle of the drawer can enable the drawer to be retracted and extended manually. Furthermore, each drawer can have a bottom with positioning elements arranged on the bottom for positioning one or more wafers and/or a transport receptacle. Whether a drawer is equipped with a transport receptacle can be recognized by means of a recognition device of the device and/or the drawer, so that the manipulator unit can subsequently pick up the transport receptacle following an automatic retraction of the drawer triggered by recognition of the equipped state of the drawer. The drawer is preferably equipped and retracted taking into account the prioritization and/or the dwell time in the processing spaces of the device. The prioritization and/or the dwell time can preferably be determined by means of step b. of the method according to the invention. As soon as the transport receptacle has been picked up by the manipulator unit, the device can indicate that the drawer can be equipped again with a transport receptacle with wafers by automatically extending the drawer and/or outputting a message, taking into account the prioritization and/or dwell time in the process spaces. A transport receptacle with finished processed wafers, i.e. in particular with contact metallizations produced on the terminal faces, can be deposited in a drawer of an output station by means of the manipulator unit, so that the transport receptacle can subsequently be removed from the drawer, which is preferably automatically extended.

Advantageously, essentially the entire process can take place fully automatically due to the interaction of the control unit, the sensor unit and the manipulator unit and can lead to optimal contact metallization of the terminal faces of wafers, several transport receptacles, preferably four transport receptacles, being able to be handled simultaneously within the device.

According to one embodiment of the device, the processing spaces of the work stations can be disposed on a processing side of the work stations, the processing side being separated from a supply side by means of a separating unit. Devices for operating and controlling the processes taking place in the processing spaces can be disposed on the supply side. The manipulator unit for handling the transport receptacle can be disposed on the separating unit. The device can be separated into areas of different cleanroom classes by means of the separating unit. For example, a room of a lower cleanroom class than on the processing side can be formed on the supply side. The operator can then equip the work stations on the processing side under conditions of a higher cleanroom class, while other work that places lower demands on cleanness, such as maintenance work on the units or equipment, can be carried out on the supply side of the device without impairing the flow of processes in the processing spaces on the processing side. In addition to the separating function, the separating unit can fulfill the function of a receiving unit, guiding unit or fastening unit for the manipulator unit, so that the manipulator unit can be arranged within the device in a simple manner and in a space-saving manner. If the work stations each have a section of the separating unit designed as a partition wall, it is possible to combine the individual modules with each other with the least possible effort, without the separating unit having to be supplemented with additional effort.

### BRIEF DESCRIPTION OF THE DRAWINGS

In the following, preferred embodiments of the invention are described in more detail with reference to the attached drawings.

FIG. 1 shows an embodiment of a device according to the invention.

FIG. 2 shows the work station of the device according to FIG. 1 in an enlarged perspective view.

FIG. 3 shows a perspective view of a drawer of an input/output station of the device according to FIG. 1.

FIG. 4 shows a perspective view of the manipulator unit having a transport receptacle.

FIG. 5 shows a perspective partial view of the manipulator unit shown in in FIG. 4.

FIG. 6 shows a perspective partial view of the device when the transport receptacle is positioned within the processing space.

FIG. 7 shows a cut through a partial view of the device when the transport receptacle is positioned within the processing space.

FIG. 8 shows a perspective partial view of the device when the transport receptacle is disposed outside of the processing space.

FIG. 9 shows a perspective partial view of the device when the transport receptacle is partially inserted into the processing space.

FIG. 10 shows a perspective partial view of the device when the transport receptacle is positioned within the processing space.

FIG. 11 shows a cut through the partial view shown in FIG. 10.

### DETAILED DESCRIPTION

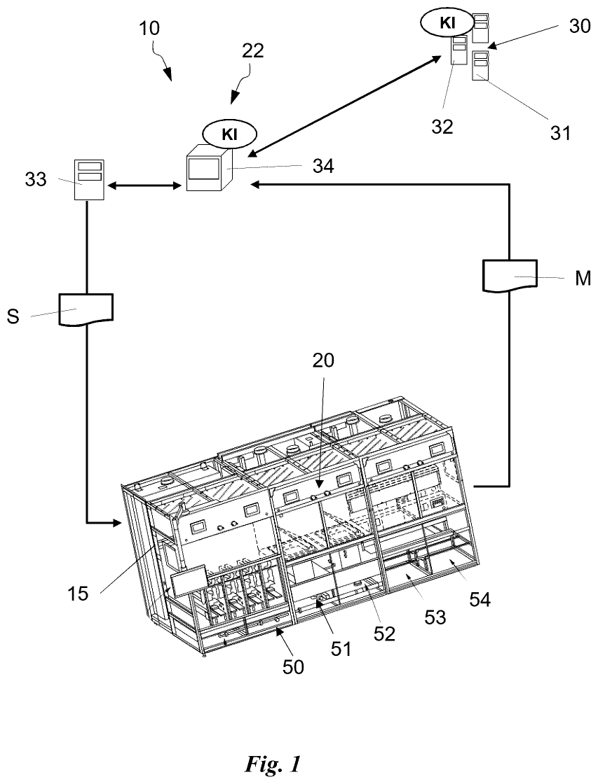

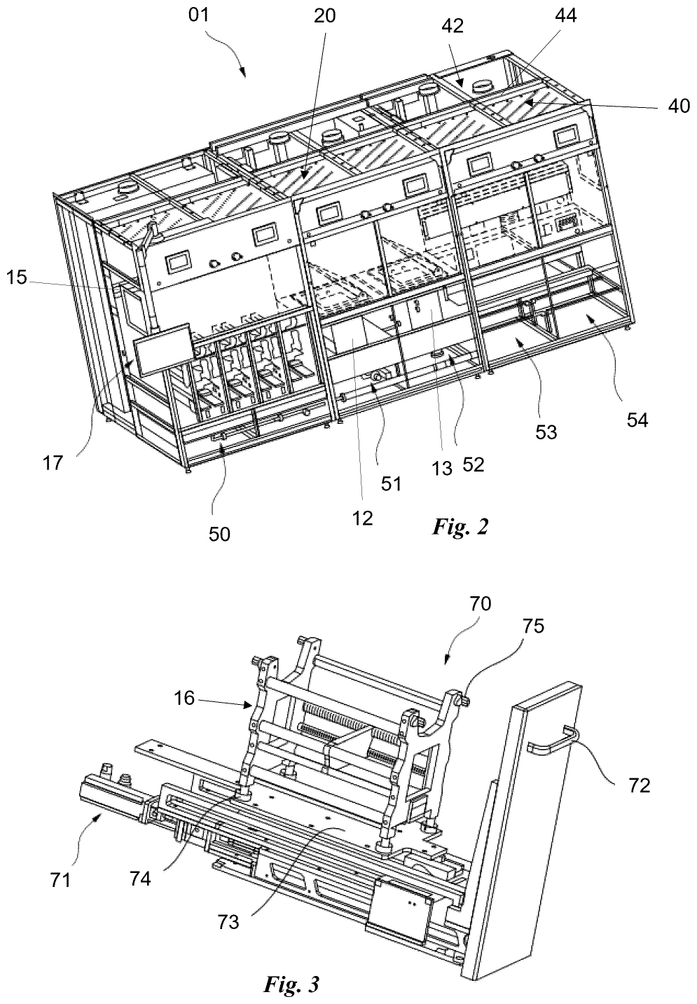

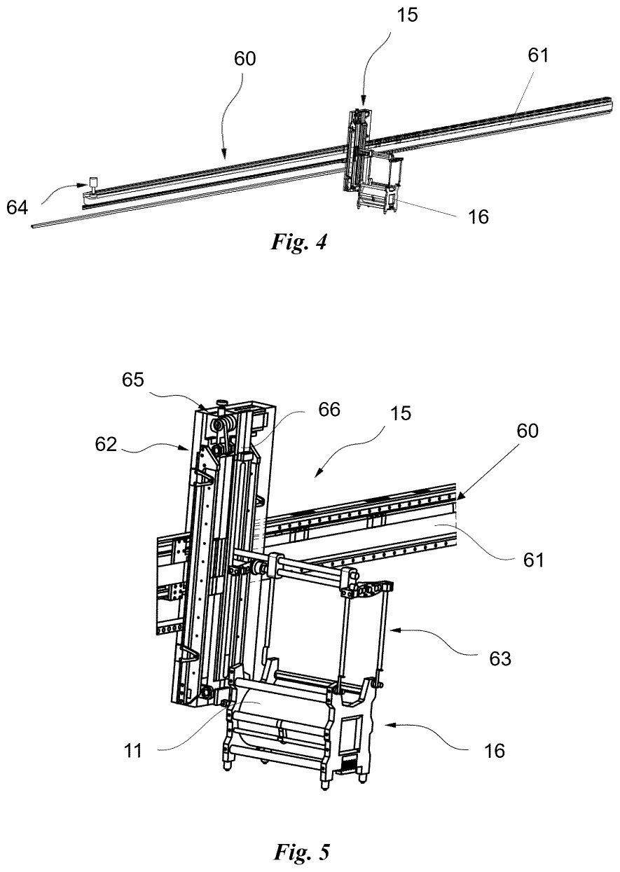

A combined view of FIGS. 1 to 11 shows a device 10 for producing contact metallizations on terminal faces of wafers 11 received in a transport receptacle 16, comprising at least one sensor unit 20, a control unit 22 and a plurality of work stations. According to the embodiment shown, the device 10 has as work stations an input/output station 50 for equipping the device 10 with transport receptacles 16, a cleaning station 51 with a processing space 12 for receiving a transport receptacle 16 with the wafers 11 received therein, a depositing station 52, a rinsing station 53 and a drying station 54. The work stations are disposed in a line. The cleaning station 51, the depositing station 52, the rinsing station 53 and the drying station 54 each have a processing space, the processing spaces of the rinsing station 53 and of the drying station 54 not being shown here, so that only the processing space 12 of the cleaning station 51 and the processing space 13 of the depositing station 52 can be seen in the illustrations of FIGS. 1 and 2. As FIG. 2 further shows, it is possible to install a separating unit 44 in the device 10 that separates the work stations into areas of different cleanroom classes in such a way that a processing side 40 is separated from a supply side 42. In the present case, there is a gray room on one side of the separating unit 44, namely on the supply side 42, and a cleanroom on the other side of the separating unit 44, namely on the processing side 40, which has a higher cleanroom class compared to the gray room and allows the operator to equip the work stations under cleanroom conditions. Another operator can, for example, carry out maintenance work on the units or equipment on the supply side 42 of the device 10 without impairing the flow of processes in the processing spaces on the processing side 40 of the device 10.

The device 10 also has a manipulator unit 15, which comprises a conveyor unit 60. The conveyor unit 60 can have a conveyor belt 61 for horizontal displacement of the gripping arm 63 and a conveyor belt 66 for vertical displacement of the gripping arm 63. Furthermore, the manipulator unit 15 has a horizontally displaceable carrier 62 connected to a conveyor belt 66 of the conveyor unit 60 with a gripping arm 63 that can be displaced vertically in relation to the carrier 62. The conveyor belt 61 is driven by a drive motor 64 of the conveyor unit 60. The carrier 62 has a conveyor belt 66 driven by a drive motor 65 of the carrier 62, by means of which the gripping arm 63 can be displaced in relation to the carrier 62. Thus, the transport receptacle 16 with the wafers 11 received therein can be fed to a processing space of the work stations in a simple manner by means of the manipulator unit 15, the sequence of feeding to the processing spaces being freely selectable. According to the method according to the invention, which can be carried out with the device 10 shown, equipping the processing spaces of the work stations takes place according to a prioritization and dwell time of the wafers 11 in a processing space determined by the method. The prioritization and dwell time is determined by the control unit 22. In addition to a server 30, in which the statistical model 32 and the databank 31 are stored, the control unit can have a programmable logic controller 33 and a user interface 34. The control unit 22 provides a control dataset S for controlling the manipulator unit 15, the control unit being able to generate the control dataset independently with the help of artificial intelligence (AI) and/or machine learning. In addition, the control dataset S can be generated and/or adapted via the user interface 34 or the user interface 17 on the device, also by an operator himself, with the support of artificial intelligence AI and/or machine learning. To generate the control dataset S, the sensor unit 20 uses at least one sensor 21 to detect a measured value M of an object property of a wafer 11 and/or of a work station. The measured values M are transmitted from the sensor unit 20 to the control unit 22 and are fed to a databank 30 and/or to a statistical model 32. The control unit 22 can be arranged at least partially remote from the work stations. In particular, the server 30 may be located remotely from the work stations. The data exchange between sensor unit 20, manipulator unit 15 and control unit 22 can be wired and/or wireless. By querying the measured value M in a databank 30, a control dataset S can be output if a control dataset S for the corresponding measured value M is stored in the databank 30. Alternatively, a prioritization and/or dwell time optimally matching the measured value M can be output by means of inference with the statistical model 32 while entering the measured value M. Taking into account the determined prioritization and/or dwell time, the control unit 22 can generate a control dataset S for the manipulator unit 15. This control dataset S preferably comprises a path planning for the manipulator unit 15 for handling the transport receptacle 16 between the work stations of the device 10. For example, the chemical composition of the liquid located in the processing space 13 of the depositing station 52 can be determined by means of the sensor 21 of the sensor unit 20, and the dwell time adapted to the chemical composition of the liquid in the processing space 13 can be determined taking into account the measured values M output by the sensor 21. The adapted dwell time in turn affects the handling of the other transport receptacles 16 located in the work stations, as the processing space 13 is occupied for a certain period of time and the manipulator unit 15 can therefore equip the other processing spaces with transport receptacles 16 during the time in which the processing space 13 is occupied. The path planning for equipping the other processing spaces is again carried out after determining a prioritization and/or dwell time and is transmitted to the manipulator unit 15 by means of the control dataset S. Due to the possibility of accessing the historical data stored in the databank 31 with regard to prioritization and dwell time as well as the possibility of determining prioritization and dwell time using a statistical model 32, the device can be optimally utilized while maintaining the high quality of the contact metallizations. In addition, the device 10 is less dependent on the experience of an operator and therefore less error-prone to operate.

As can be seen in particular from a combined view of FIGS. 2 and 3, the input/output station 50 can be designed with drawers 70, as shown in FIG. 3 taken in isolation. The drawers 70 can each be automatically retracted and extended by means of a drive motor 71 of the drawer 70. A respective handle 72 of the drawer 70 also allows the drawer 70 to be manually retracted and extended by an operator. Furthermore, each drawer 70 has a bottom 73 with positioning elements 74 arranged on the bottom 73 for positioning the transport receptacle 16. Furthermore, receiving elements 75 of the transport receptacle 16 can be seen, which serve to grip the transport receptacle 16 by means of the gripping arm 63.

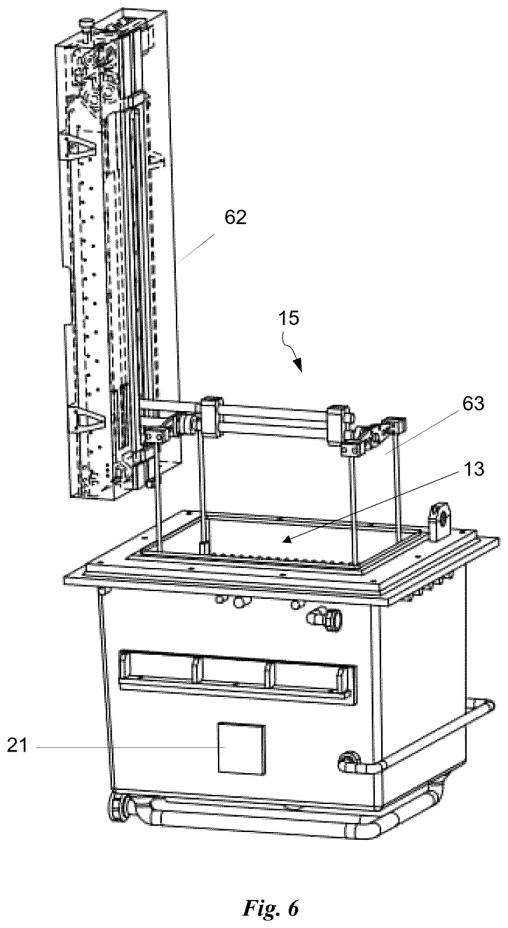

As can be clearly seen once again from a combined view of FIGS. 6 to 11, the transport receptacle 16 with the wafers 11 positioned vertically therein can be inserted into or removed from the processing space 13 of a depositing station 52, the transport receptacle 16 inserted in the processing space 13 being supported on abutment elements 14 arranged at the bottom of the processing space 13, which is designed as a basin. The same applies to the insertion and/or removal of the transport receptacle 16 from the cleaning station 51, the rinsing station 53 and the drying station 54, which may also have a processing space in the form of a basin.

According to the invention, the depositing station 52 comprises a basin arrangement with a basin forming the processing space 13 for receiving a solution of metal dissolved in a liquid for deposition on a terminal face of a plurality of wafers 11 received in a transport receptacle 16 which can be received in the processing space 13 and which can be inserted into the processing space 13 from above to carry out a deposition process and/or can then be removed again from the processing space 13 and can be handled by means of the manipulator unit 15. The depositing station 52 can have a storage container and circulation pumps which serve to supply the processing space 13 with circulating liquid. Furthermore, a storage container for storing a contact metal, for example for storing nickel, and a storage container for nitric acid can be provided, the storage container for the contact metal supplying the processing space 13 with contact metal for a constant contact metal content in the processing space 13 and the nitric acid on the one hand serving to produce the solution required in the processing space 13 and on the other hand also serving for cleaning purposes, for example in the cleaning station 51.

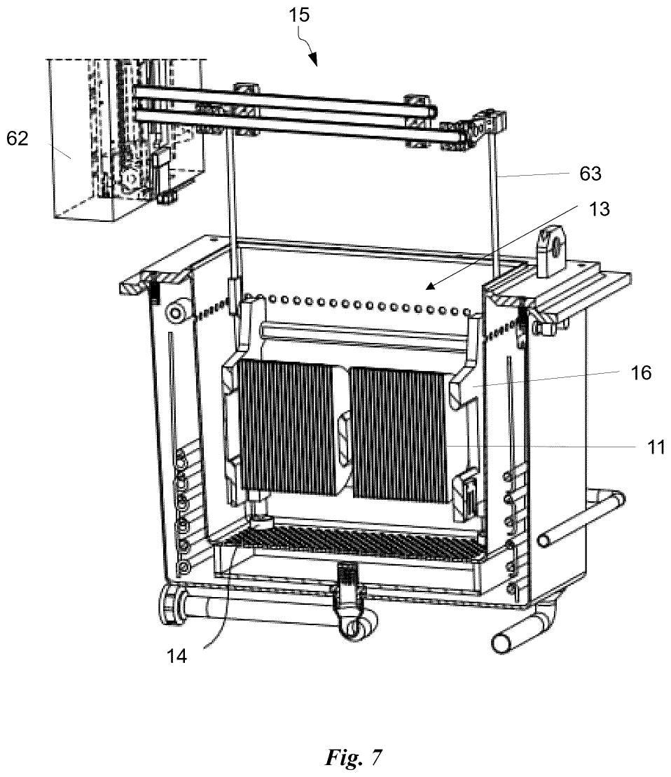

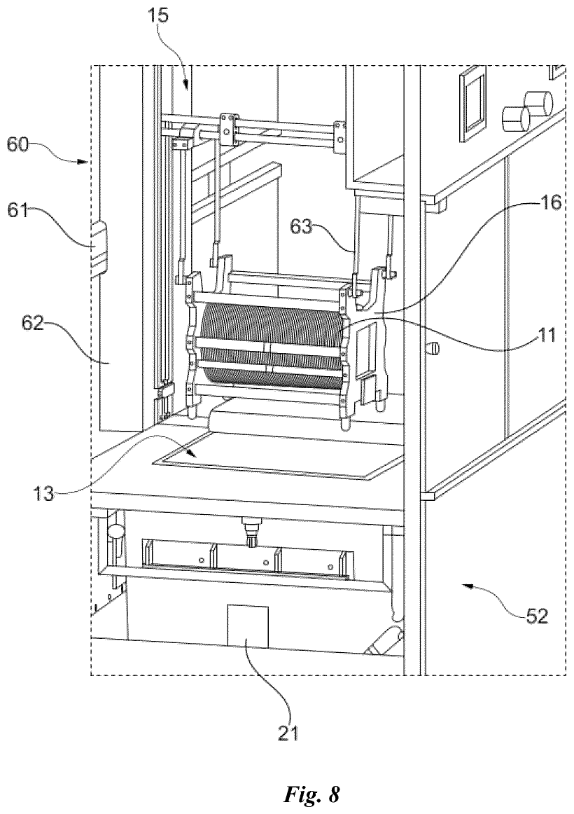

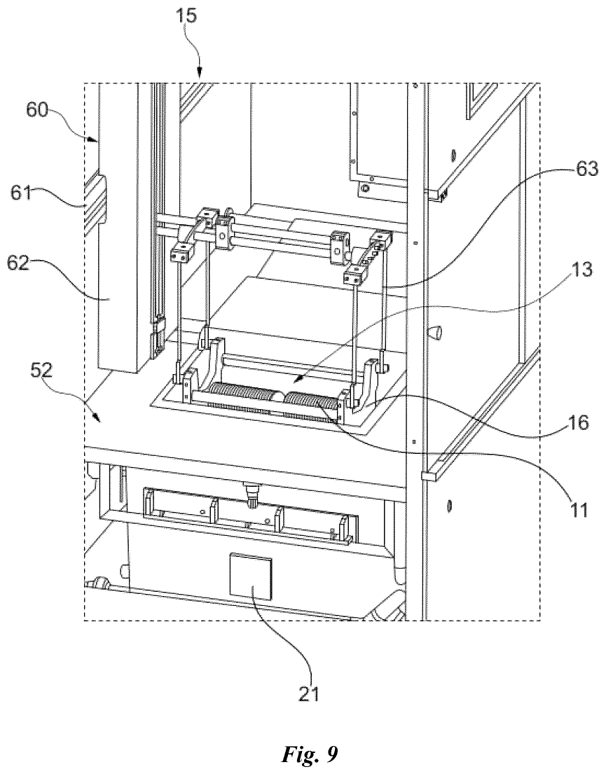

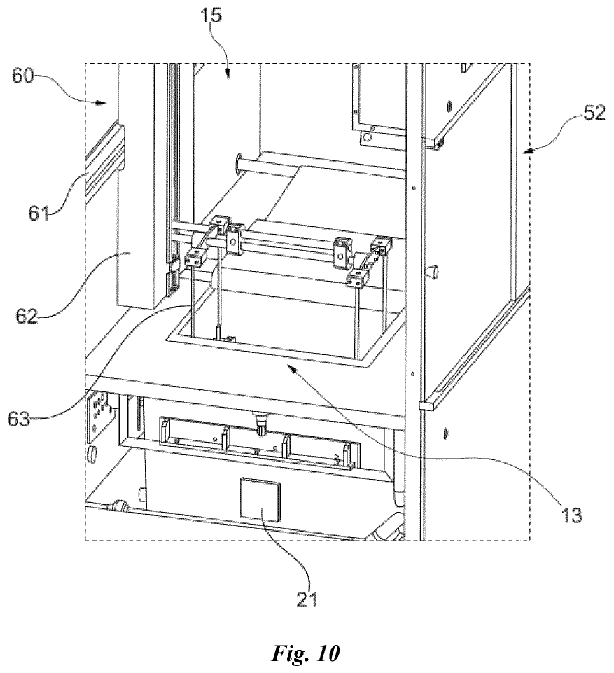

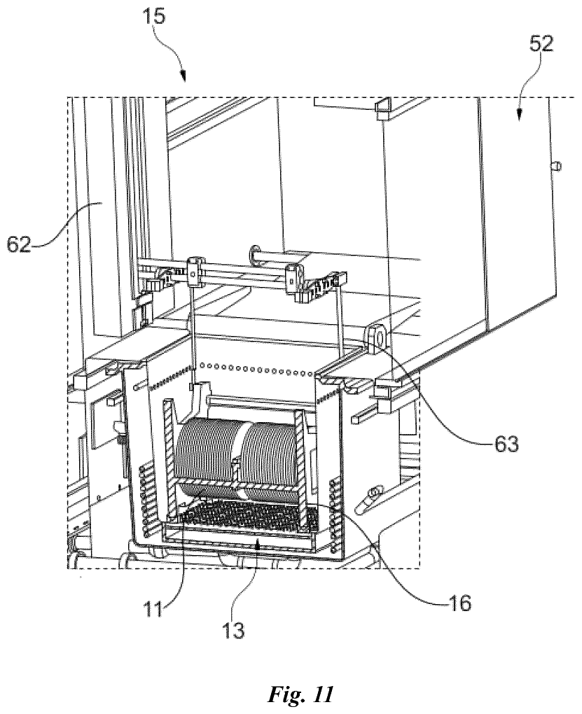

FIG. 7 shows a section through the illustration shown in FIG. 6, whereby it can be seen that the transport receptacle 16 is almost completely inserted in the processing space 13, but does not yet come to rest on the abutment elements 14. In contrast, in FIG. 8 the transport receptacle 16 is held outside the processing space 13 by the gripping arm 63 of the manipulator unit 15. By means of the conveyor belt 66 arranged on the carrier 62, the gripping arm 63 can be lowered so that the transport receptacle 16 with the wafers 11 held therein can be inserted into the processing space. In FIG. 9, the gripping arm 63 is lowered further compared to the position of the gripping arm s 63 shown in FIG. 8 and the transport receptacle 16 is partially inserted into the processing space 13 of the depositing station 52. As can be seen from FIG. 10 and in particular from the sectional view of the illustration shown in FIG. 11, the transport receptacle 16 in FIGS. 10 and 11 is lowered further by means of the gripping arm 63 compared to the position shown in FIG. 9 and is fully inserted in the processing space 13, so that the transport receptacle 16 is made to rest on the abutment elements 14.

### LIST OF REFERENCE SIGNS

10 device
11 wafer
12 processing space cleaning
13 processing space deposition
14 abutment element
15 manipulator unit
16 transport receptacle
17 user interface work station
20 sensor unit
21 sensor
22 control unit
30 server
31 databank
32 statistical model
33 programmable logic controller (PLC)
34 user interface HMI
40 processing side
42 supply side
44 separating unit
50 input/output station
51 cleaning station
52 depositing station
53 rinsing station
54 drying station
60 conveyor unit
61 conveyor belt horizontal
62 carrier
63 gripping arm
64 drive motor
65 drive motor
66 conveyor belt vertical
70 drawer
71 drive motor
72 handle
73 bottom
74 positioning clement
75 receiving clement
M measured value
S control dataset

1. A method for producing contact metallizations on terminal faces of wafers (11) by means of a manipulator unit (15) for handling the wafers (11) and by means of a plurality of work stations, preferably disposed in a line, each having a processing space (12, 13) for receiving the wafers (11), the plurality of work stations comprising as a work station at least one depositing station (52), which has a processing space (13) for receiving a solution of contact metal dissolved in a carrier liquid for deposition on the terminal faces of the wafers (11), the method comprising the following steps:
a. detecting at least one measured value (M) of at least one object property of a wafer (11) and/or of a work station by means of at least one sensor (21) of a sensor unit (20).
b. determining a prioritization of equipping the processing spaces (12, 13) and/or a dwell time of the wafers (11) in a processing space (12, 13) by means of querying the measured value (M) in a databank (30) and/or by means of inference using a statistical model (32) while entering the measured value (M).
c. generating a control dataset(S) for the manipulator unit (15) while taking into account the prioritization and/or dwell time determined in step b.
d. handling the wafers (11) by means of the manipulator unit (15) according to the control dataset (S).

2. The method according to claim 1, wherein the object property in step a. is a property inherent to the wafer (11) or to the work station, a property influenced by the surroundings or a property assigned to the wafer (11) or to the work station.

3. The method according to claim 1, wherein the prioritization or the dwell time in step b. is determined while taking into account the handling paths between the processing spaces (12, 13) to be equipped, while taking into account the handling times between the processing spaces (12, 13) to be equipped, while taking into account the inertia force during handling, while taking into account the processing times in the processing spaces (12, 13) to be equipped or while taking into account the tolerance bands of the processing times in the processing spaces (12, 13) to be equipped.

4. The method according to claim 1, wherein the prioritization determined in step b. comprises a sequence of the equipping of the processing spaces (12, 13) or a path planning of the manipulator unit (15).

5. The method according to claim 1, wherein the databank (31) or the statistical model (32) is upgraded or updated in step b. with the measured value (M) measured in step a. or with the prioritization determined in step b. or with the dwell time determined in step b.

6. The method according to claim 1, wherein the handling of the wafers (11) comprises gripping, picking up, lifting, transporting, releasing or equipping a processing space (12, 13) of a work station with a wafer.

7. The method according to claim 1, wherein step d. further comprises evaluating the handling and obtaining an evaluation.

8. The method according to claim 7, wherein step d. further comprises updating or upgrading the control dataset(S) while taking into account the evaluation.

9. The method according to claim 1, wherein at least three transport receptacles (16) receiving a plurality of wafers (11) are handled in the plurality of work stations by means of the manipulator unit (15).

10. A device (10) for producing contact metallizations on terminal faces of wafers (11), the device comprising a manipulator unit (15) for handling the wafers (11) and a plurality of work stations, preferably disposed in a line, each having a processing space (12) for receiving the wafers (11), the plurality of work stations comprising as a work station at least one depositing station (52), which has a processing space (13) for receiving a solution of contact metal dissolved in a carrier liquid for deposition on the terminal faces of a wafer (11), wherein the manipulator unit (15) allows equipping the processing spaces (12, 13) with the wafers (11) according to a selectable prioritization or a selectable dwell time in the processing spaces (12, 13), the device comprising a sensor unit (20) and a control unit (22) and the control unit (22) being configured to control a movement of the manipulator unit (15) for equipping the processing spaces (12, 13) as a function of at least one measured value (M) detected by the sensor unit (20).

11. The device according to claim 10, wherein at least one sensor (21) of the sensor unit (20) is a position sensor, an acceleration sensor, a weight sensor, a temperature sensor or a chemical sensor for analyzing the liquid in one of the processing spaces (12, 13) or for monitoring the deposition on the terminal faces of the wafers (11).

12. The device according to claim 10, wherein a transport receptacle (16) having a plurality of wafers (11) received therein is comprised, the processing space (12, 13) being configured to receive the transport receptacle (16) with a plurality of wafers (11) received therein and the manipulator unit (15) being configured to handle the transport receptacle (16).

13. The device according to claim 10, wherein the manipulator unit (15) has a horizontally displaceable carrier (62), the carrier (62) being connected to a conveyor belt (61) of a conveyor unit (60) and having at least one gripping arm (63) displaceable vertically in relation to the carrier (62).

14. The device according to claim 10, wherein the plurality of work stations has as a work station at least one input/output station (50) for equipping the device (10) with at least one transport receptacle (16),
at least one cleaning station (51) having a processing space (12) for receiving the transport receptacle (16) with the wafers (11) received therein,
at least one rinsing station (53) having a processing space for receiving the transport receptacle (16) with the wafers received therein and for removing any residue on the wafer surfaces/or at least one drying station (54) having a processing space for receiving the transport receptacle (16) with the wafers (11) received therein.

15. The device according to claim 10, wherein a processing side (40) of the work stations is separated from a supply side (42) of the work stations by means of a separating unit (44), the processing spaces (12, 13) being disposed on the processing side (40) and units for operating and for controlling the processes taking place in the processing spaces (12, 13) being disposed on the supply side (42), and the manipulator unit for handling the transport receptacle (16) being disposed on the separating unit (44).
